(19) United States
(12) Patent Application Publication
(10) Pub. No.: US 2014/0065837 A1
(43) Pub. Date: Mar. 6, 2014

(54) METHOD OF BONDING LAYERS FOR THIN FILM DEPOSITION

(71) Applicant: ILYAS KHAYRULLIN, HOPEWELL JUNCTION, NY (US)

(72) Inventor: ILYAS KHAYRULLIN, HOPEWELL JUNCTION, NY (US)

(73) Assignee: EMAGIN CORPORATION, Hopewell Junction, NY (US)

(21) Appl. No.: 13/967,518

(22) Filed: Aug. 15, 2013

Related U.S. Application Data
(60) Provisional application No. 61/694,281, filed on Aug. 29, 2012.

(51) Int. Cl. H01L 21/02

(52) U.S. Cl. CPC H01L 21/02518
USPC 438/758

(57) ABSTRACT

A method of bonding together at least two aligned layers, at least one having an active surface, in a semiconductor manufacturing process using a holding member having spaced sections. Each layer has a bonding surface opposite a back surface. The method includes preparing at least two bonding pads on the back surface of each layer and positioning close together the bonding surface of each layer. Aligning the bonding pads of the layers together and inserting the aligned layers between sections of at least one holding member and aligning the sections with the bonding pads of the layers. Applying bonding compound to the aligned bonding pads adjacent the aligned sections of the holding member.

### CROSS-REFERENCE TO RELATED APPLICATION

This application claims the benefit of provisional patent application Ser. No. 61/694,281 filed in the United States Patent and Trademark Office on Aug. 26, 2012.

### BACKGROUND OF THE INVENTION

1. Field of the Invention

This present invention relates generally to semiconductor fabrication devices and more particularly is directed to method of bonding aligned layers prior to thin film deposition during the fabrication of electronic display devices.

2. Description of the Related Art

Devices and methods for joining two or more layers directly is the focus of the present invention commonly employed in the manufacture of semiconductors. Layers are solid, commonly planar, substances onto which a layer of another substrate, mask or wafer is applied and adheres. In the case of the present invention, layers commonly include a silicon substrate coupled with a shadow mask wafer. However, alternative embodiments may include thin slices in a variety of different shapes of layered substrate or wafer material including silicon, silicon dioxide, glass, metal shadow mask, photolithography mask, aluminum, germanium, gallium arsenide, indium phosphide, oxide, sapphire, or an alloy of silicon or germanium. These serve as the foundation upon which electronic devices such as diodes, transistors, and integrated circuits (ICs) are deposited. In the manufacture of ICs, thin wafers into which electronic devices are etched or deposited usually define the wafer material.

In addition to semiconductors, alternative electronics may be produced by the process of the present invention wherein different fabrication processes after bonding are utilized. Mostly notable, electrical insulators are contemplated.

Improved methods for bonding wafers are needed that extend the capabilities of bonding substrate manufacturing technology. While prior art units utilizing complex frames and fixtures may be suitable for the particular purpose employed, or for general use, they would not be as suitable for the purposes of the present invention as disclosed hereafter.

It is, therefore, a primary object of the present invention to provide method of bonding together at least two aligned layers in a semiconductor manufacturing process using a holding member in order to improve the fabrication process by securing together aligned layers while rotating during thin film depositing.

It is another object of the present invention to provide a device for bonding wafers in a semiconductor manufacturing process that allows two aligned wafers to be moved as a pair during thin film deposition without the use of complex frames and fixture technologies.

It is another object of the present invention to provide a method of bonding wafers in a semiconductor manufacturing process that allows wafers to be later separated without leaving contamination debris on active surfaces.

It is another object of the present invention to provide a method of bonding any type of substrate or wafer and mask handling instrumentation in a manufacturing process where two layers, masks or any other flat objects must be aligned with respect to one another and held together for processing and thereafter separated without leaving contamination on predetermined surfaces.

### BRIEF SUMMARY OF THE INVENTION

In accordance with one aspect of the present invention, method of bonding together at least two aligned layers in a semiconductor manufacturing process is provided using a holding member having spaced sections and a clamp. The method includes providing a first layer having a first bonding surface opposite a first back surface and providing a second layer having a second bonding surface opposite a second back surface. Next, aligning the bonding surfaces of the first and second layers and then clamping together with the clamp the aligned first and second layers. After which, preparing at least one bonding pad on the back surface of the first layer and at least one bonding pad on the back surface of the second layer. Then, aligning the bonding pads of the first and second layers before inserting the aligned layers between sections of at least one holding member. Next, aligning the sections of at least one holding member with the bonding pads before applying bonding compound to the aligned bonding pads and aligned sections of the holding member. Lastly, removing the clamp.

The method may also include separating at least two aligned layers by removing the bonding compound, removing the holding means and removing the bonding pads.

The method may also include the first layer being a silicon or glass substrate.

The method may also include the second layer being a shadow mask or photolithography mask wafer.

The method may also include the bonding pad being processed by photolithography, vacuum evaporation, sputtering or atomic layer depositions.

The method may also include applying bonding compound including compounds of low temperature melting point metals or adhesives.

In accordance with an additional embodiment, method of bonding together at least two aligned layers in a semiconductor manufacturing process is provided using a holding member having spaced sections. The method includes providing a first layer having a first bonding surface opposite a first back surface and providing a second layer having a second bonding surface opposite a second back surface. Next, aligning the bonding surfaces of the first and second layers before preparing at least one bonding pad on the back surface of the first layer and at least one bonding pad on the back surface of the second layer. Then, the method includes aligning the bonding pads of the first and second layers before inserting the aligned layers between sections of at least one holding member. Next, aligning the sections of at least one holding member with the bonding pads and applying bonding compound to the aligned bonding pads and the aligned sections of the holding member.

The method may also include separating at least two aligned layers by removing the bonding compound, removing the holding means and removing the bonding pads.

The method may also include the first layer being a silicon or glass substrate.

The method may also include the second layer being a shadow mask or photolithography mask wafer.

The method may also include the bonding pad being processed by photolithography, vacuum evaporation, sputtering or atomic layer depositions.

The method may also include applying bonding compound including compounds of low temperature melting point metals or adhesives.

In accordance with an additional embodiment, method of bonding together an aligned substrate and shadow mask wafer are provided wherein the substrate includes an active surface for uniformly accepting a thin film thereon while the aligned substrate and wafer is rotating. The method includes providing the substrate having the first active surface opposite a first back surface and providing the shadow mask wafer having a bonding surface opposite a second back surface. Then, aligning the active surface of the substrate adjacent the bonding surface of the shadow mask wafer. Next, preparing at least one bonding pad on the back surface of each of the substrate and shadow wafer mask. Then, aligning at least one bonding pad of the substrate with at least one bonding pad of the shadow mask wafer. After which, inserting the aligned substrate and wafer between sections of at least one holding member before aligning the sections of at least one holding member with the bonding pads of the aligned substrate and wafer. Lastly, applying bonding compound to the aligned bonding pads and the aligned sections of the holding member.

The method may also include separating the aligned substrate and wafer by removing the bonding compound, removing the holding means and removing the bonding pads.

The method may also include the substrate being a silicon or glass substrate.

The method may also include the bonding pad being processed by photolithography, vacuum evaporation, sputtering or atomic layer depositions.

The method may also include applying bonding compound including compounds of low temperature melting point metals or adhesives.

In accordance with an additional embodiment, method of removably coupling together at least two layers having at least one active surface, using a holding member having spaced sections and a clamp, for uniformly depositing a thin film thereon is provided. The method includes aligning the layers in a stack, wherein the stack has a top and bottom surface before engaging the top and bottom surfaces of the stack with at least one clamp. Then, positioning at least one bonding pad on the top surface and at least one bonding pad on the bottom surface of the stack. Next, inserting the stack between sections of the holding member and bonding together the sections of the holding member with the bonding pads. Lastly, removing the clamp.

The method may also include separating the aligned stack by removing the bonding compound, removing the holding means and removing the bonding pads.

The method may include one layer being a silicon or glass substrate.

The method may include one layer being a shadow mask or photolithography mask wafer.

### BRIEF DESCRIPTION OF THE SEVERAL VIEWS OF THE DRAWINGS

To these and to such other objects that may hereinafter appear, the present invention relates to method of bonding layers in a semiconductor manufacturing process as described in detail in the following specification and recited in the annexed claims, taken together with the accompanying drawings, in which like numerals refer to like parts in which:

FIGS. 1-5 are cross sectional views of successive stages of a wafer bonding process used to form a bonded substrate and shadow mask wafer stack in accordance with an embodiment of the invention;

FIG. 1A is an enlarged view of the substrate of FIG. 1;

FIG. 3A is an enlarged view of the substrate of FIG. 3; and

FIG. 4A is an enlarged view of the substrate of FIG. 4.

To the accomplishment of the above and related objects the invention may be embodied in the form illustrated in the accompanying drawings. Attention is called to the fact, however, that the drawings are illustrative only. Variations are contemplated as being part of the invention, limited only by the scope of the claims.

### DETAILED DESCRIPTION OF THE INVENTION

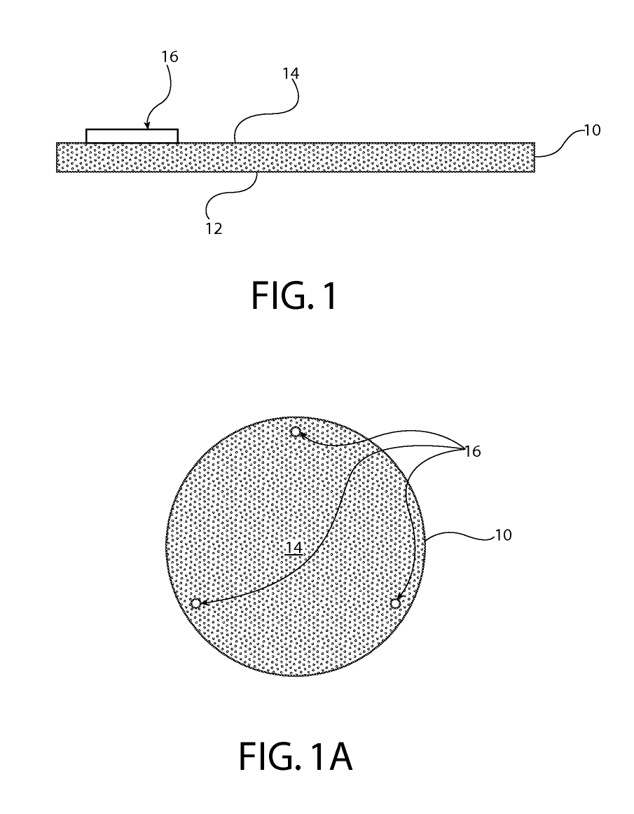

With reference to FIG. 1 and in accordance with an embodiment of the invention, a layer 10 is provided. Preferably, the layer 10 is a thin flat object and may be, but is not limited to, a silicon substrate, glass substrate, metal shadow mask, photolithography mask, wafer or other thin flat object of round, rectangular or other shape.

In its broadest context, the method includes bonding any type of layer and mask handling instrumentation where the layer and mask must be aligned with respect to one another and held together following processing and thereafter separated without leaving contamination on active surfaces.

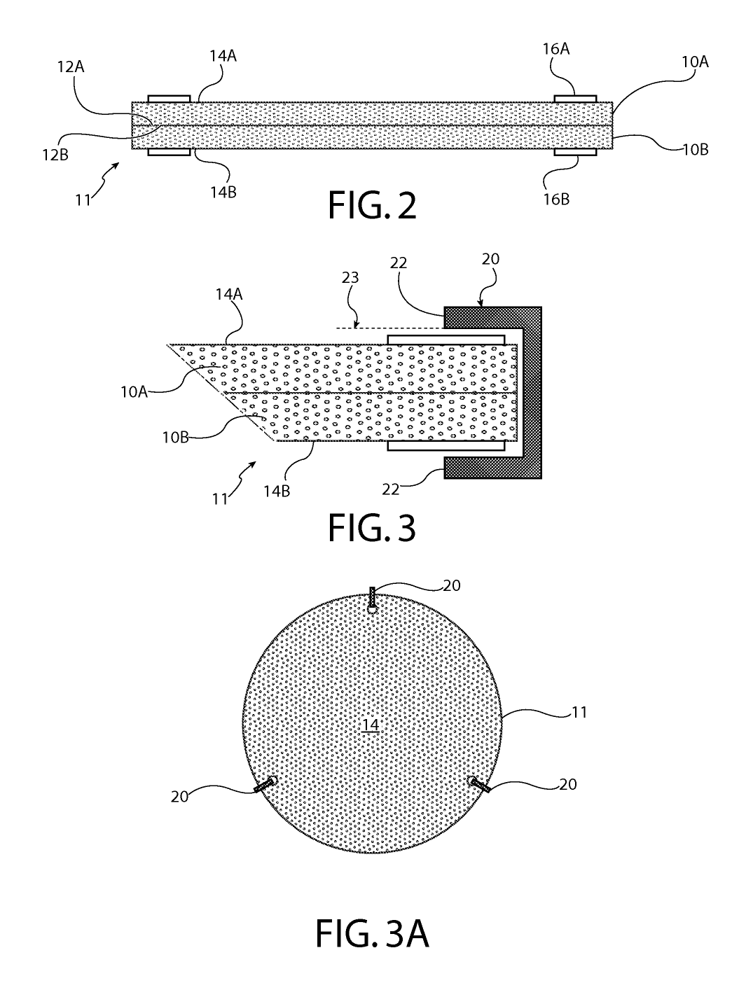

The method first includes preparing at least two layers 10 for bonding in a stack, each layer having a bonding surface 12 opposite a back surface. In particular, a first layer 10A is preferably a silicon substrate, and a second layer 10B is preferably a shadow mask wafer. The first layer 10A has a first bonding surface 12A opposite a first back surface 14A while the second wafer 10B, has a second bonding surface 12B opposite a second back surface 14B. While in a stack, the first back surface 14A is the top and the second back surface 14B is the bottom. The back surface 14A of the silicon substrate 10A is preferably polished down to a specified thickness to form an active surface area 15 (shown in FIG. 2) where devices will be fabricated thereon. More particularly, the active surface 15 is suitable for deposition of thin film thereon for use in the semiconductor industry as an organic light emitting diode display device. In the preferred embodiment, the shadow mask wafer 10B has a plurality of openings 17 extending therethrough for allowing the active surface 15 of the substrate 10A to be deposited thereon (shown in FIG. 2).

Next, at least two bonding pads 16 are prepared on the back surfaces 14A, 14B of the first and second layers 10A, 10B. In the preferred embodiment, shown in FIG. 1A, three bonding pads 16 are equally spaced about the outer perimeter of the layer 10. Preferably, the bonding pads 16 are positionable adjacent the active surface 15 of the silicon substrate 10A. Preferably, the bonding pads 16 are made of metal or other like material compatible with bonding compounds. The bonding pads 16 are preferably formed on the layers 10 by methods including, but not limited to, photolithography, vacuum evaporation, sputtering, atomic layer deposition and others.

FIG. 2 illustrates the next step of the method wherein the layers 10 are first brought into close contact and aligned such that the bonding surface 12A of the first silicon substrate 10A is in close proximity to the bonding surface 12B of said second shadow mask wafer 10B. Then, the bonding pads 16A of the first silicon substrate 10A are aligned with the bonding pads 16B of the second shadow mask wafer 10B. Next, the bonding surfaces 12A, 12B are temporarily clamped together by any suitable mechanical or other method creating an aligned stack of layers 11.

FIG. 3 illustrates the next step of the method. Herein, at least one means for holding together at least two aligned layers 11 without compromising said active surface 15 is provided. More particular, means includes holding member 20 having two spaced apart sections 22. Preferably, the holding member 20 is a rigid bonding or welding clip, substantially U-shaped and made of material compatible with bonding compound and bounding pads. The clip 20 is preferably provided in a geometry and configuration so as to not scratch or displace the pair of aligned layers 11 during the following steps. Specifically, the aligned layers 11 are inserted between the sections 22 of the clip or holding member 20. Then, the sections 22 of each holding member 20 are aligned with the bonding pads of the aligned layers 11 such that a space or gap is defined between the sections 22 of the holding member 20 and the bonding pads. The gap 23 is defined between the back surfaces 14A, 14B of the layers 11 and the sections 22 of the holding member 20.

FIG. 3A illustrates the preferred embodiment of the present invention wherein three bonding clips 20 are in position around the perimeters of the aligned layers 11. A plurality of clips 20 are provided so as to use as many as necessary to provide good adequate grip to the aligned layers 11. The clips 20 insure that the layers 11 remain perfectly aligned during spinning and rotating during thin film deposition which is paramount to the present invention.

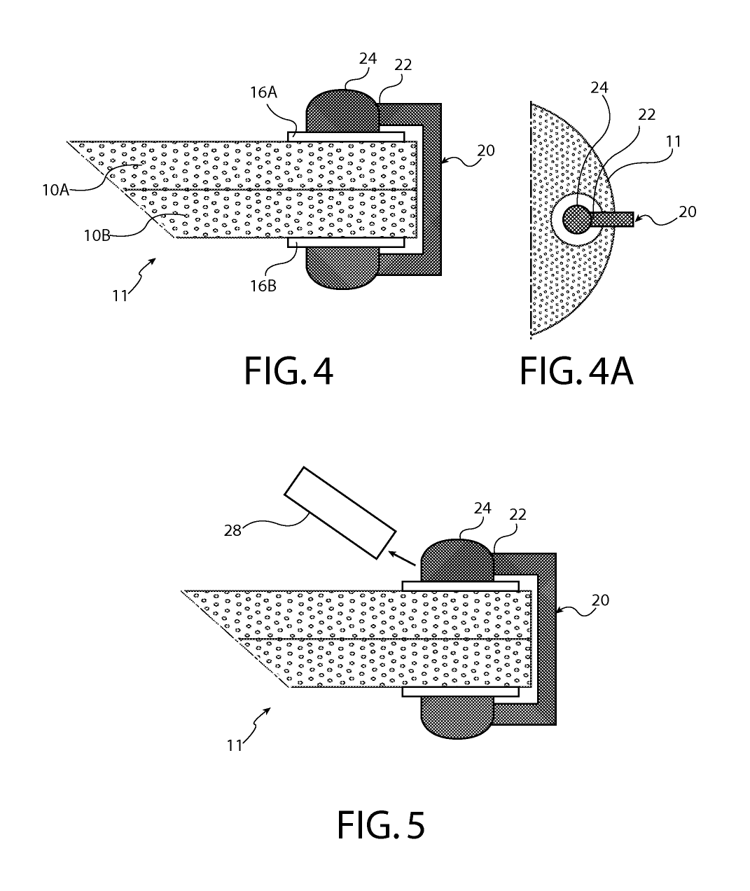

FIGS. 4 and 4A illustrate the next step of the present method wherein bonding compound 24 is applied to the aligned bonding pads 16 adjacent the aligned sections 22 of the holding member 20. Preferably, the bonding compound 24 is applied using any means compatible with bonding compound properties. Such compound can be, but is not limited to, low temperature melting point metals (Iridium, for example) or adhesives. The bonding compound 24 together with the bonding pads 16 and holding member 20 provides a firm permanent bond together of the pair of aligned layers 11. The holding member 20 provides rigid stability for securing the aligned layers 11 together between sections 22 eliminating even minute displacement. Once the bonding compound 24 is applied to the bonding pads 16 and sections 22 of the holding member 20, the mechanical clamps temporarily holding together the aligned layers 11 are removed.

Once fixed in alignment, the aligned layers 11 are processed as necessary and able to rotate or spin during thin film deposition without fear of misaligning. Thus, eliminating damage caused by misaligned layers.

FIG. 5 illustrates means for separating at least two layers after processing without contaminating the active surface 15 of the first silicon substrate 10A, specifically by removal of the bonding compound 24 and holding members 20 from the aligned layers 11. Preferably, the bonding compound 24 is removed using heat, solvent, or any other like means 28 compatible with bonding compound properties. Such removal may be facilitated by the use of, but not limited to, vacuum suction or swiping. Once the clips or holding members 20 are removed, the aligned layers 11 can be separated without risk of damage or contamination to active surfaces. The first silicon substrate 10A is then able to be used as selected, while the shadow mask wafer is able to be cleaned and reused for processing another substrate. In addition, the bonding pads are removable from each layer 10, either individually or later during fabrication when the excess perimeter area of the layer 10 is cut.

In conclusion, herein is presented method of bonding aligned layers in a semiconducting manufacturing process prior to thin film deposition. The invention is illustrated by example in the drawing figures, and throughout the written description. It should be understood that numerous variations are possible, while adhering to the inventive concept. Such variations are contemplated as being a part of the present invention. While only one preferred embodiments of the present invention has been disclosed for purposes of illustration, it is obvious that many modifications and variations could be made thereto. It is intended to cover all of those modifications and variations, which fall within the scope of the present invention as defined by the following claims.

We claim:

1. A method of bonding together at least two aligned layers in a semiconductor manufacturing process using a holding member having spaced sections and a clamp, the method comprising the steps of:
a. providing a first layer having a first bonding surface opposite a first back surface;
b. providing a second layer having a second bonding surface opposite a second back surface;
c. aligning the bonding surfaces of said first and second layers;
d. clamping together with the clamp said aligned first and second layers;
e. preparing at least one bonding pad on said back surface of said first layer and at least one bonding pad on said back surface of said second layer;
f. aligning the bonding pads of said first and second layers;
g. inserting said aligned layers between sections of at least one holding member;
h. aligning said sections of said at least one holding member with said bonding pads;
i. applying bonding compound to said aligned bonding pads and said aligned sections of said holding member; and
j. removing the clamp.

2. The method of claim 1 further comprising separating said at least two aligned layers by removing said bonding compound, removing said holding means and removing said bonding pads.

3. The method of claim 1 wherein the first layer is a silicon or glass substrate.

4. The method of claim 1 wherein the second layer is a shadow mask or photolithography mask wafer.

5. The method of claim 1 wherein said bonding pad is processed by a method from the group consisting of photolithography, vacuum evaporation, sputtering or atomic layer depositions.

6. The method of claim 1 wherein applying bonding compound includes compounds of low temperature melting point metals or adhesives.

7. A method of bonding together at least two aligned layers in a semiconductor manufacturing process using a holding member having spaced sections, the method comprising the steps of:
a. providing a first layer having a first bonding surface opposite a first back surface;
b. providing a second layer having a second bonding surface opposite a second back surface;
c. aligning the bonding surfaces of said first and second layers;
d. preparing at least one bonding pad on said back surface of said first layer and at least one bonding pad on said back surface of said second layer;
e. aligning the bonding pads of said first and second layers;
f. inserting said aligned layers between sections of at least one holding member;
g. aligning said sections of said at least one holding member with said bonding pads; and
h. applying bonding compound to said aligned bonding pads and said aligned sections of said holding member.

8. The method of claim 7 further comprising separating said at least two aligned layers by removing said bonding compound, removing said holding means and removing said bonding pads.

9. The method of claim 7 wherein the first layer is a silicon or glass substrate.

10. The method of claim 7 wherein the second layer is a shadow mask or photolithography mask wafer.

11. The method of claim 7 wherein said bonding pad is processed by a method from the group consisting of photolithography, vacuum evaporation, sputtering or atomic layer depositions.

12. The method of claim 7 wherein applying bonding compound includes compounds of low temperature melting point metals or adhesives.

13. A method of bonding together an aligned substrate and shadow mask wafer, wherein said substrate includes an active surface for uniformly accepting a thin film thereon while said aligned substrate and wafer is rotating, the method comprising the steps of:
a. providing said substrate having said first active surface opposite a first back surface;
b. providing said shadow mask wafer having a bonding surface opposite a second back surface;
c. aligning the active surface of said substrate adjacent the bonding surface of said shadow mask wafer;
d. preparing at least one bonding pad on said back surface of each said substrate and shadow wafer mask;
e. aligning said at least one bonding pad of said substrate with said at least one bonding pad of said shadow mask wafer;
f. inserting said aligned substrate and wafer between sections of at least one holding member;
g. aligning said sections of said at least one holding member with said bonding pads of said aligned substrate and wafer; and
h. applying bonding compound to said aligned bonding pads and said aligned sections of said holding member.

14. The method of claim 13 further comprising the step of separating said aligned substrate and wafer by removing said bonding compound, removing said holding means and removing said bonding pads.

15. The method of claim 13 wherein the substrate is a silicon or glass substrate.

16. The method of claim 13 wherein said bonding pad is processed by a method from the group consisting of photolithography, vacuum evaporation, sputtering or atomic layer depositions.

17. The method of claim 13 wherein applying bonding compound includes compounds of low temperature melting point metals or adhesives.

18. A method of removably coupling together at least two layers having at least one active surface, using a holding member having spaced sections and a clamp, for uniformly depositing a thin film thereon, the method comprises:
a. aligning said layers in a stack, wherein said stack has a top and bottom surface;
b. engaging the top and bottom surfaces of said stack with at least one clamp;
c. positioning at least one bonding pad on said top surface and at least one bonding pad on said bottom surface of said stack;
d. inserting said stack between sections of the holding member;
e. bonding together said sections of said holding member with said bonding pads; and
f. removing said clamp.

19. The method of claim 18 further comprising the step of separating said aligned stack by removing said bonding compound, removing said holding means and removing said bonding pads.

20. The method of claim 18 wherein one layer is a silicon or glass substrate.

21. The method of claim 18 wherein one layer is a shadow mask or photolithography mask wafer.
